(19) United States
(12) Patent Application Publication
(10) Pub. No.: US 2025/0095967 A1
(43) Pub. Date: Mar. 20, 2025

(54) PLASMA SOURCE WITH MULTIPLE EXTRACTION APERTURES

(71) Applicant: Applied Materials, Inc., Santa Clara, CA (US)

(72) Inventors: Morgan D. Evans, Manchester, MA (US); Peter F. Kurunczi, Cambridge, MA (US)

(21) Appl. No.: 18/370,155

(22) Filed: Sep. 19, 2023

(51) Int. Cl. H01J 37/32

(52) U.S. Cl. CPC H01J 37/32458; H01J 37/3211; H01J 37/3244; H01J 37/32715; H01J 37/32899; H01J 2237/327

(57) ABSTRACT

A plasma source having two extraction apertures is disclosed. The extraction apertures are not co-planar, allowing a scanned workpiece to be impacted by particles or ions from two different directions during a single scan pass. The chamber housing of the plasma source may be cylindrical or may have a polygonal cross-section. In some embodiments, external plates are mounted to the chamber housing to provide defining apertures which serve to further collimate the particles or ions that exit each extraction aperture. Various different plasma generators may be utilized with this plasma source, including internal antenna elements, external coils, cathodes, filaments and other mechanisms.

### FIELD

Embodiments of the present disclosure relate to a plasma source with multiple extraction apertures.

### BACKGROUND

The fabrication of a semiconductor device involves a plurality of discrete and complex processes. Accordingly, many prior art designs were optimized for ion implantation. Recently, in addition to ion implantation, there has been a transition to other processes, such as deposition, etching and other material changing processes, such as amorphization.

Angled processes refer to those in which the beam strikes the substrate at a non-zero angle. For consistency, an angle of 0° is defined as one in which the beam strikes the substrate at an angle perpendicular to the surface of the substrate. Angled beams have many applications. For example, they may be used to implant a sidewall of a fin structure or a trench. Angled beams may also be used for etching processes, deposition processes and other applications. Previous designed have proven to yield angles which were typically less than 45° and had low flux and a broad distribution of angles.

In some systems, a plasma source directs a beam toward the workpiece at an non-zero angle. However, in some applications, it is beneficial to perform symmetric processing of the workpiece. For example, it may be beneficial to treat a 3D feature on both sides with a beam of ions or radicals. Currently this is done by scanning the workpiece through the angled beam, and after the entire workpiece has been processed, the workpiece is rotated 180° and then scanned again.

This process is effective but may be time consuming as it uses two scanning passes of the workpiece with a 180° rotation between these two passes.

Additionally, there is value in achieving high angles, such as greater than 60°, with a small distribution of angles and high flux, which may be ions and/or radicals.

Therefore, it would be advantageous if there was a system that had multiple extraction apertures, so that both surfaces of a 3D feature may be processed during a single scan. Further, it would be beneficial if this source was able to create large angles with a small distribution of angles and high flux.

### SUMMARY

A plasma source having two extraction apertures is disclosed. The extraction apertures are not co-planar, allowing a scanned workpiece to be impacted by particles or ions from two different directions during a single scan pass. The chamber housing of the plasma source may be cylindrical or may have a polygonal cross-section. In some embodiments, external plates are mounted to the chamber housing to provide defining apertures which serve to further collimate the particles or ions that exit each extraction aperture. Various different plasma generators may be utilized with this plasma source, including internal antenna elements, external coils, cathodes, filaments and other mechanisms.

According to one embodiment, a plasma source is disclosed. The plasma source comprises a chamber housing defining a plasma chamber; and a plasma generator to create a plasma within the plasma chamber; wherein a first portion of the chamber housing includes a first extraction aperture; and a second portion of the chamber housing includes a second extraction aperture, wherein the first portion and the second portion are not coplanar. In some embodiments, a first line perpendicular to the first portion and passing through the first extraction aperture and a second line perpendicular to the second portion and passing through the second portion intersect within the plasma chamber. In certain embodiments, the first line and the second line form an angle of between 30 and 150 degrees. In certain embodiments, the first line and the second line intersect at a center of the plasma chamber. In some embodiments, the plasma source comprises a first external plate having a first defining aperture disposed outside the plasma chamber proximate the first extraction aperture, and a second external plate having a second defining aperture disposed outside the plasma chamber proximate the second extraction aperture, wherein the first external plate and the second external plate are biased at a same voltage as the chamber housing, such that the first defining aperture narrows a path of travel for particles exiting the first extraction aperture and the second defining aperture narrows a path of travel for particles exiting the second extraction aperture. In some embodiments, the plasma source comprises a first external plate having a first electrode aperture disposed outside the plasma chamber proximate the first extraction aperture, and a second external plate having a second electrode extraction aperture, wherein the first external plate and the second external plate are negatively biased relative to the chamber housing using an electrode power supply so as to attract ions through the first extraction aperture and the second extraction aperture. In certain embodiments, the plasma source comprises at least a second set of external plates, wherein the second set of external plates are disposed outside the first external plate and second external plate, respectively, and are biased at a different voltage than the first external plate and the second external plate. In some embodiments, the chamber housing comprises a cylindrical body, wherein the first extraction aperture and the second extraction aperture are disposed on the cylindrical body. In some embodiments, the chamber housing comprises a body having a polygonal cross-section, and the first extraction aperture and the second extraction aperture are disposed on different sides of the polygon. In certain embodiments, the different sides are adjacent. In certain embodiments, the different sides are not adjacent.

According to another embodiment, a processing system is disclosed. The processing system comprises the plasma source described above and a workpiece holder, movable in a scanning direction, wherein a workpiece disposed on the workpiece holder is exposed to particles or ions exiting the first extraction aperture at some locations along the scanning direction, and is exposed to particles or ions exiting the second extraction aperture at other locations along the scanning direction.

According to another embodiment, a processing system is disclosed. The processing system comprises a plasma source, comprising: a chamber housing including a cylindrical body and two ends that define a plasma chamber; a first extraction aperture and a second extraction aperture disposed along the cylindrical body; and at least one antenna element disposed within the plasma chamber to generate a plasma; a scan motor; and a workpiece holder, movable in a scanning direction by the scan motor, wherein a workpiece disposed on the workpiece holder is exposed to particles or ions exiting the first extraction aperture at some locations along the scanning direction, and is exposed to particles or ions exiting the second extraction aperture at other locations along the scanning direction. In some embodiments, a first line perpendicular to the cylindrical body and passing through the first extraction aperture and a second line perpendicular to the cylindrical body and passing through the second portion intersect within the plasma chamber and form an angle of between 30° and 150°. In certain embodiments, the at least one antenna element comprises three antenna elements, wherein the three antenna elements are arranged such that a peak plasma density is located at an intersection of the first line and the second line. In some embodiments, the processing system comprises a first external plate having a first defining aperture disposed outside the plasma chamber proximate the first extraction aperture, and a second external plate having a second defining aperture disposed outside the plasma chamber proximate the second extraction aperture, wherein the first external plate and the second external plate are biased at a same voltage as the chamber housing, such that the first defining aperture narrows a path of travel for particles exiting the first extraction aperture and the second defining aperture narrows a path of travel for particles exiting the second extraction aperture. In some embodiments, the processing system comprises a first external plate having a first electrode aperture disposed outside the plasma chamber proximate the first extraction aperture, and a second external plate having a second electrode extraction aperture, wherein the first external plate and the second external plate are negatively biased relative to the chamber housing using an electrode power supply so as to attract ions through the first extraction aperture and the second extraction aperture. In certain embodiments, the processing system comprises at least a second set of external plates, wherein the second set of external plates are disposed outside the first external plate and second external plate, respectively, and are biased at a different voltage than the first external plate and the second external plate.

According to another embodiment, a processing system is disclosed. The processing system comprises a plasma source, comprising: a chamber housing including a body having a polygonal cross-section and two ends that define a plasma chamber; a first extraction aperture and a second extraction aperture disposed on two different sides of the body; and at least one antenna element disposed within the plasma chamber to generate a plasma; a scan motor; and a workpiece holder, movable in a scanning direction by the scan motor, wherein a workpiece disposed on the workpiece holder is exposed to particles or ions exiting the first extraction aperture at some locations along the scanning direction, and is exposed to particles or ions exiting the second extraction aperture at other locations along the scanning direction.

### BRIEF DESCRIPTION OF THE FIGURES

For a better understanding of the present disclosure, reference is made to the accompanying drawings, which are incorporated herein by reference and in which:

FIG. 1 is a block diagram of a plasma source having two extraction apertures according to one embodiment;

FIG. 2 is a block diagram of a plasma source having extraction apertures according to a second embodiment;

FIG. 3 is a block diagram of a plasma source having two extraction apertures according to a third embodiment;

FIG. 4 is a block diagram of a plasma source having two extraction apertures according to a fourth embodiment; and

FIG. 5 is a block diagram of a plasma source having two extraction apertures according to a fifth embodiment.

### DETAILED DESCRIPTION

As described above, angled semiconductor processes, such as angled implant, deposition and etch processes are becoming increasing common in the semiconductor industry. Therefore, a system that allows 3D features of a workpiece to be processed on both sides during a single scanning pass, would be very beneficial.

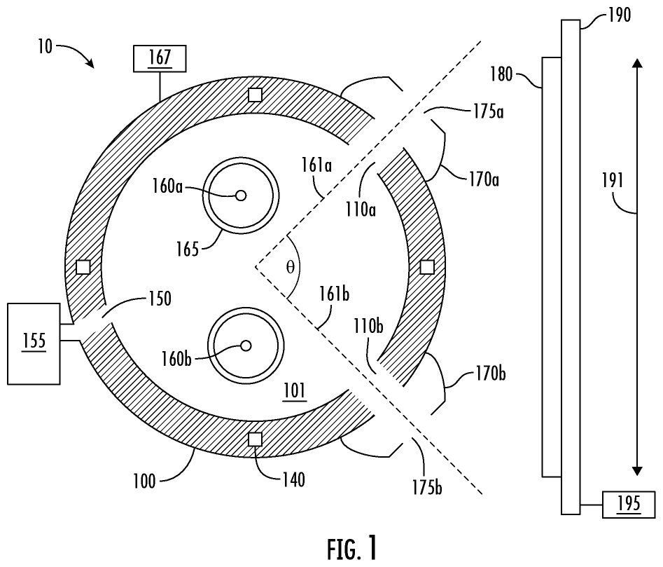

FIG. 1 shows a cross-sectional view of a plasma source 10 having multiple extraction apertures which allows for the extraction of two beams of angled ions and/or neutral particles according to one embodiment. The plasma source 10 includes a chamber housing 100, having a cylindrical body, and two closed ends, which define a plasma chamber 101. The two ends are parallel to the surface of the page and are not shown for clarity. The body of the chamber housing 100 has an inner surface having an inner diameter and an outer surface having an outer diameter. Additionally, the chamber housing 100 also includes a first extraction aperture 110a and a second extraction aperture 110b disposed along the perimeter of the cylindrical body. Each extraction aperture 110a, 110b is an opening in the chamber housing 100 and has a width, which is the direction between the two ends. Each extraction aperture 110a, 110b also has a height, which is in the circumferential direction. In some embodiments, the extraction apertures 110a, 110b extend across the entire width of the chamber housing 100. In other embodiments, the extraction apertures 110a, 110b may not extend to the two ends.

A first line 161a may be formed between the center of the plasma chamber 101 and the center of the first extraction aperture 110a. This first line 161a may be perpendicular to the chamber housing 100 at the position where it passes through the first extraction aperture 110a. A second line 161b may be formed between the center of the plasma chamber 101 and the center of the second extraction aperture 110b. Similarly, this second line 161b may be perpendicular to the chamber housing 100 at the position where it passes through the second extraction aperture 110b. The angle, θ, formed between the first line 161a and the second line 161brepresents a difference in the extraction angles between the two extraction apertures 110a, 110b. In some embodiments, this angle, θ, may be between 30° and 150°. Assuming that the plasma source 10 is configured such that the tilt angles are complementary, this allows tilt angles between 15° and 75°. In other words, while FIG. 1 shows the tilt angles as 45° and −45°, the extraction apertures 110a, 110b may be arranged such that the tilt angles are larger or smaller than this value. Note that while two extraction apertures are shown, additional extraction apertures may be added.

The plasma source 10 may also include one or more liners disposed within the plasma chamber 101 along the interior wall of the chamber housing 100. In some embodiments, one or more magnets 140 may be disposed in the chamber housing 100. The plasma source 10 also includes a gas inlet 150, which is in communication with a gas source 155.

In this embodiment, one or more antenna elements 160a, 160bare disposed within the plasma chamber 101. In some embodiments, the antenna elements 160a, 160b are constructed of a conductive material, such as a metal, and may be protected by an insulating cover 165. The insulating cover 165 may be quartz in some embodiments. The antenna elements 160a, 160b may be powered using an RF power supply 167. These antenna elements 160a, 160b serve as a plasma generator. Note that the disclosure is not limited to this plasma generator. For example, in other embodiments, the plasma generator may include a coil disposed outside the chamber housing 100, a cathode disposed within the plasma chamber 101, a filament disposed within the plasma chamber 101, or another plasma generator.

In one particular embodiment, there may be two antenna elements 160a, 160b, as shown in FIG. 1, wherein the current flows in opposite directions through the two antenna elements 160a, 160b.

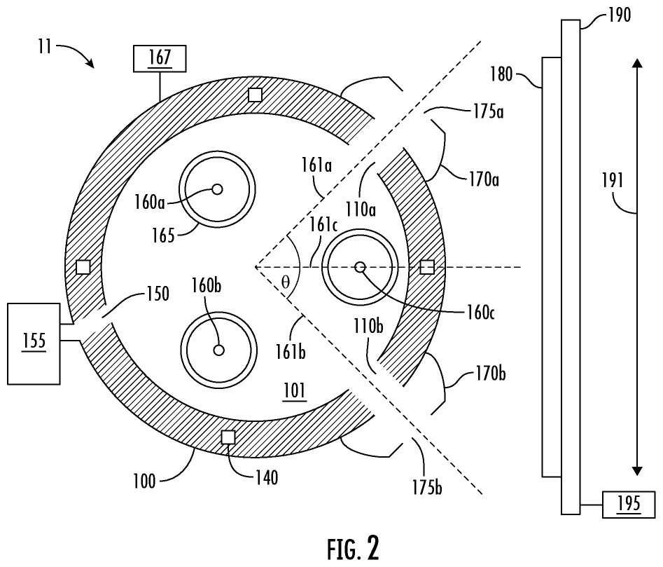

In another embodiment, shown in FIG. 2, the plasma source 11 may include three antenna elements, where current flows through two antenna elements 160a, 160b in one direction and through the third antenna element 160c in the opposite direction. As shown in FIG. 2, the third antenna element 160c may be located along a third line 161c that is equidistant from the two extraction apertures 110a, 110b. Further, the other two antenna elements 160a, 160b may be configured to center the peak plasma density at the center of the plasma chamber 101.

Additionally, in certain embodiments, such as those shown in FIGS. 1-4, two external plates 170a, 170b are affixed to the chamber housing 100. Each of these external plates 170a, 170b may include a respective aperture, referred to as a defining aperture 175a, 175b. Each defining aperture 175a, 175b is aligned with a respective extraction aperture 110a, 110b. The defining apertures 175a, 175b provide additional collimation of the particles that exit the extraction apertures 110a, 110b.

In some embodiments, the external plates 170a, 170b are electrically connected to the chamber housing 100. In n these embodiments, the external plates 170a, 170b do not attract charged ions from the plasma chamber 101. Rather, the defining apertures 175a, 175b serve to confine the path of neutral particles and radicals that are extracted from the plasma chamber 101.

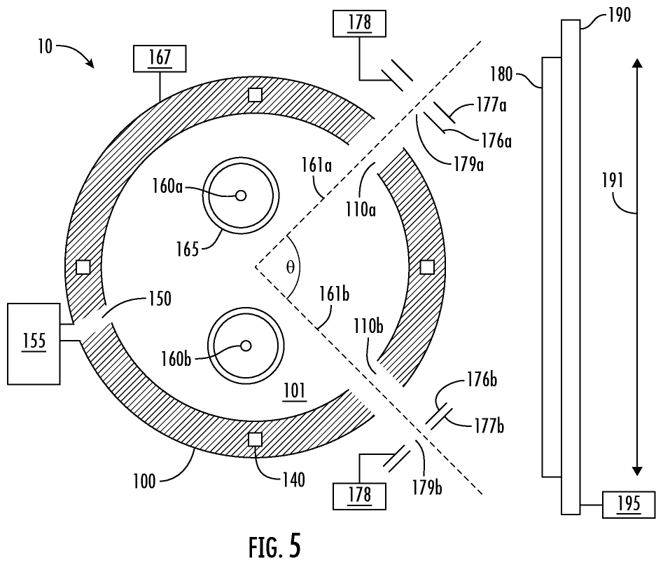

In other embodiments, such as that shown in FIG. 5, the external plates 176a, 176b may be electrically isolated from the chamber housing 100, such as through the use of an insulator. The first external plate 176a is disposed outside the first extraction aperture 110a and the second external plate 176b is disposed outside the second extraction aperture 110b. In these embodiments, a voltage different from the voltage applied to the chamber housing 100 may be applied to the external plates 176a, 176b. In certain embodiments, the external plates 176a, 176b may be negatively biased relative to the chamber housing 100 using electrode power supply 178. This negative bias is applied so as to attract positive ions from the plasma chamber 101. Thus, in this embodiment, the external plates 176a, 176b serve as extraction electrodes. Furthermore, in some embodiments, a second set of external plates 177a, 177b may be disposed beyond the external plates 176a, 176b, respectively. This second set of external plates 177a, 177b may be positively biased or grounded and may serve as suppression electrodes. Additional sets of electrodes may also be present. The external plates are aligned such that an electrode aperture 179a, 179b is created and is aligned with the respective extraction aperture 110a, 110b.

The workpiece 180 is disposed on a workpiece holder 190. The workpiece holder 190 may be scanned in a scanning direction 191 using scan motor 195.

Thus, in operation, one or more processing gasses are supplied from the gas source 155 to the plasma chamber 101 through the gas inlet 150. RF power from the RF power supply 167 is provided to the antenna elements 160. The antenna elements 160 create RF energy, which causes the processing gasses within the plasma chamber 101 to become ionized and form a plasma. Magnets 140 serve to direct the plasma toward the center of the plasma chamber 101 and away from the chamber housing 100.

In the embodiment shown in FIG. 1 where the external plates 170a, 170b are electrically connected to the chamber housing 100, particles, which may be neutrals or radicals, drift out of the plasma chamber 101 through the extraction apertures 110a, 110b. Some of these particles then pass through the defining apertures 175a, 175b and proceed toward the workpiece 180. Through use of the defining apertures, a more collimated beam of particles may be created.

In the embodiment shown in FIG. 5 where the external plates 176a, 176b are electrically biased separate from the chamber housing 100, ions are drawn through the extraction apertures 110a, 110b by the voltage applied to the external plates 176a, 176b. These ions then pass through the electrode apertures 179a, 179band proceed toward the workpiece 180.

The workpiece 180 is scanned in the scanning direction 191. The scanning direction 191 is perpendicular to the width of the extracted beams. Note that, at some locations along the scanning direction 191, the workpiece 180 is exposed to the particles or ions exiting the first extraction aperture 110a. As the workpiece 180 continues along scanning direction 191, there are other locations along the scanning direction 191 where the workpiece 180 is exposed to the particles or ions exiting the second extraction aperture 110b. Thus, the entire workpiece 180 is exposed to both beams without rotating or otherwise reorienting the workpiece 180.

Thus, in this embodiment, the plasma source has a chamber housing 100 that includes a cylindrical body and two ends, which define a plasma chamber 101. The cylindrical body includes two or more extraction apertures 110a, 110b that are positioned along the circumferential direction. A plasma generator, such as antenna elements, is used to generate a plasma within the plasma chamber 101. The extraction apertures 110a, 110b may be separated by between 30° and 150°. Further, external plates 170a, 170b may be disposed outside the extraction apertures 110a, 110b to further collimate the ions and/or particles exiting the extraction apertures 110a, 110b.

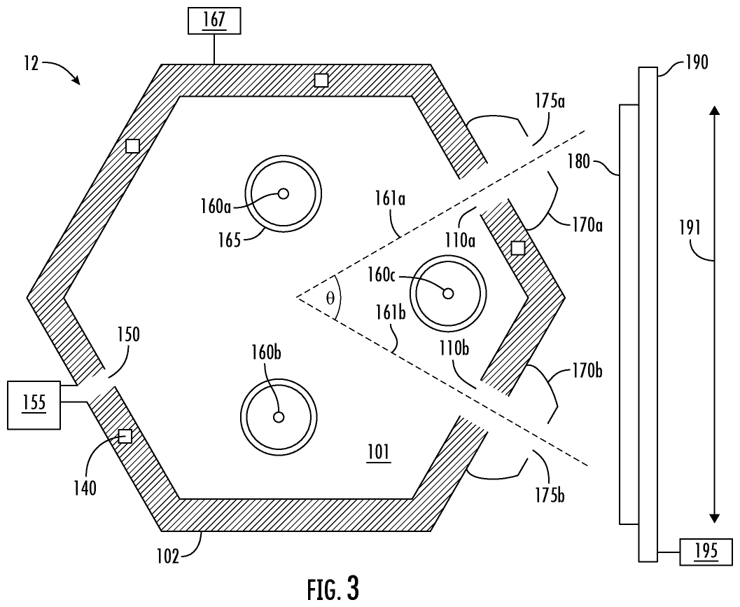

While FIGS. 1-2 and 5 show a plasma source with a cylindrical body, other embodiments are also possible. FIG. 3 shows a plasma source 12 that includes a chamber housing 102 that includes a body having a hexagonal cross-section and two ends. In this embodiment, the extraction apertures 110a, 110b are disposed on two adjacent sides of the body. The angle between these two adjacent sides of the body determines the two tilt angles. For example, FIG. 3 shows a body having a cross-section of a regular hexagon, and thus, the angle, θ, between the first line 161a and the second line 161b is 60°, so the tilt angles are 30° and −30°. However, the angle between these two sides may be changed to achieve a different tilt angle. Further, while FIG. 3 shows three antenna elements 160a, 160b, 160c it is understood that a different number of antenna elements (such as is shown in FIG. 1) may also be employed. Further, the antenna elements 160a, 160b, 160c may be replaced with a different plasma generator as noted earlier. The rest of the plasma source 12 may be as described above. Further, while FIG. 3 shows the extraction apertures disposed on adjacent sides of the body, it is understood that the extraction apertures may be disposed on any two sides. Further, while FIG. 3 shows the external plates 170a, 170b electrically connected to the chamber housing 102, it is understood that the external plates 176a, 176b and the electrode power supply 178 shown in FIG. 5 may be utilized with the chamber housing 102 of FIG. 3.

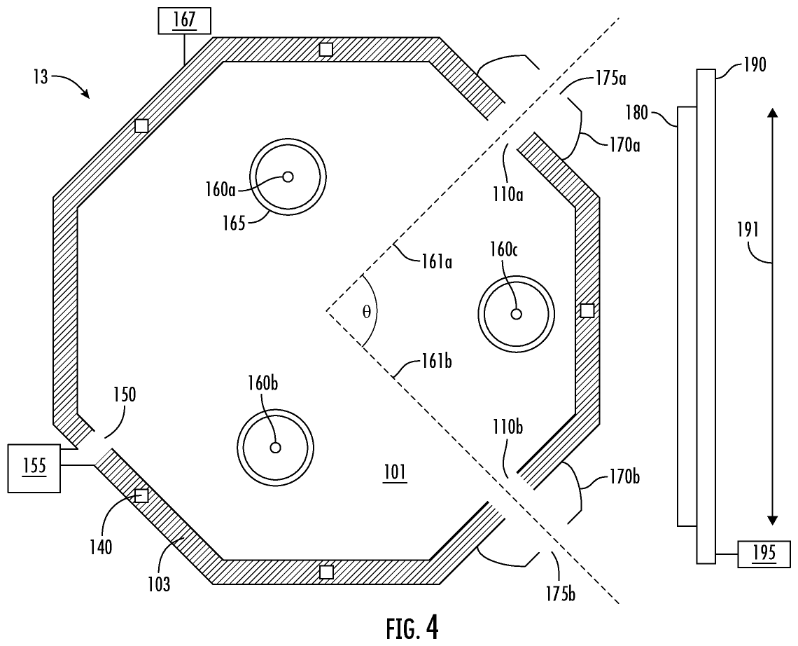

FIG. 4 shows a plasma source 13 having a chamber housing 103 that has a body having an octagonal cross-section and two ends. In this embodiment, the first extraction aperture 110a and second extraction aperture 110b are not disposed on adjacent sides of the chamber housing 103. Rather, there is a side between the two sides that include the extraction apertures. Thus, if the body is a regular octagon, the angle, θ, between the first line 161a and the second line 161b is 90°, so the tilt angles are −45° and 45°. However, the angle between these two sides may be changed to achieve a different tilt angle. Further, while FIG. 4 shows three antenna elements 160a, 160b, 160c, it is understood that a different number of antenna elements (such as is shown in FIG. 1) may also be employed. Further, the antenna elements 160a, 160b, 160c may be replaced with a different plasma generator as noted earlier. The rest of the plasma source 13 may be as described above. Further, while FIG. 4 shows the external plates 170a, 170b electrically connected to the chamber housing 103, it is understood that the external plates 176a, 176b and electrode power supply 178 shown in FIG. 5 may be utilized with the chamber housing 103 of FIG. 4.

Note that if the embodiment shown in FIG. 3 is modified such that there is a side between the two sides that include the extraction apertures, the tilt angles become −60° and 60°. Further, note that if the embodiment of FIG. 4 is modified such that there are two sides between the sides that include the extraction apertures, the tilt angles become −67.5° and 67.5°.

Further, as is clear from the above, the shape of the chamber housing may be any suitable shape. For example, the body of the chamber housing may be cylindrical. Alternatively, the body of the chamber housing may have a polygonal cross-section, where the two extraction apertures are located on different sides of the polygon. In some embodiments, these different sides may be adjacent to one another. However, in other embodiments, these different sides are not adjacent. For example, there may be one or more sides disposed between the sides that include the extraction apertures.

However, in all embodiments, the present disclosure utilizes two extraction apertures 110a, 110b, wherein these two extraction apertures are disposed on two portions of the chamber housing that are not co-planar. Further, as described above, the first line 161a and the second line 161b intersect within the plasma chamber 101 and form an angle that may be between 30° and 150°. In certain embodiments, the first line 161a and the second line 161b meet at the center of the plasma chamber 101. In some embodiments, the antenna elements 160 may be arranged so that the peak plasma density is located at the intersection of the first line 161a and the second line 161b.

The embodiments described above in the present application may have many advantages. First, as described above, conventionally, to perform two complementary directional processes, the workpiece is rotated by 180° after each scan pass. This is time consuming and reduces throughput. By incorporating multiple extraction apertures in the plasma source, two different directional processes may be performed during one scan pass. Further, by proper arrangement of the plasma generator, the flux exiting each extraction aperture 110a, 110b may be greater than is typically achieved by existing systems. Further, the plasma sources described herein may be useful for various types of processes, including ion implantation, deposition, etching, and material changing processes, such as amorphization.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A plasma source comprising:
a chamber housing defining a plasma chamber; and
a plasma generator to create a plasma within the plasma chamber;
wherein a first portion of the chamber housing includes a first extraction aperture; and a second portion of the chamber housing includes a second extraction aperture, wherein the first portion and the second portion are not coplanar.

2. The plasma source of claim 1, wherein a first line perpendicular to the first portion and passing through the first extraction aperture and a second line perpendicular to the second portion and passing through the second extraction aperture intersect within the plasma chamber.

3. The plasma source of claim 2, wherein the first line and the second line form an angle of between 30 and 150 degrees.

4. The plasma source of claim 2, wherein the first line and the second line intersect at a center of the plasma chamber.

5. The plasma source of claim 1, further comprising a first external plate having a first defining aperture disposed outside the plasma chamber proximate the first extraction aperture, and a second external plate having a second defining aperture disposed outside the plasma chamber proximate the second extraction aperture, wherein the first external plate and the second external plate are biased at a same voltage as the chamber housing, such that the first defining aperture narrows a path of travel for particles exiting the first extraction aperture and the second defining aperture narrows a path of travel for particles exiting the second extraction aperture.

6. The plasma source of claim 1, further comprising a first external plate having a first electrode aperture disposed outside the plasma chamber proximate the first extraction aperture, and a second external plate having a second electrode aperture disposed outside the plasma chamber proximate the second extraction aperture, wherein the first external plate and the second external plate are negatively biased relative to the chamber housing using an electrode power supply so as to attract ions through the first extraction aperture and the second extraction aperture.

7. The plasma source of claim 6, further comprising at least a second set of external plates, wherein the second set of external plates are disposed outside the first external plate and second external plate, respectively, and are biased at a different voltage than the first external plate and the second external plate.

8. The plasma source of claim 1, wherein the chamber housing comprises a cylindrical body, wherein the first extraction aperture and the second extraction aperture are disposed on the cylindrical body.

9. The plasma source of claim 1, wherein the chamber housing comprises a body having a polygonal cross-section, wherein the first extraction aperture and the second extraction aperture are disposed on different sides of the polygon.

10. The plasma source of claim 9, wherein the different sides are adjacent.

11. The plasma source of claim 9, wherein the different sides are not adjacent.

12. A processing system, comprising:
the plasma source of claim 1; and
a workpiece holder, movable in a scanning direction, wherein a workpiece disposed on the workpiece holder is exposed to particles or ions exiting the first extraction aperture at some locations along the scanning direction, and is exposed to particles or ions exiting the second extraction aperture at other locations along the scanning direction.

13. A processing system, comprising:
a plasma source, comprising:
a chamber housing including a cylindrical body and two ends that define a plasma chamber;
a first extraction aperture and a second extraction aperture disposed along the cylindrical body; and
at least one antenna element disposed within the plasma chamber to generate a plasma;
a scan motor; and
a workpiece holder, movable in a scanning direction by the scan motor, wherein a workpiece disposed on the workpiece holder is exposed to particles or ions exiting the first extraction aperture at some locations along the scanning direction, and is exposed to particles or ions exiting the second extraction aperture at other locations along the scanning direction.

14. The processing system of claim 13, wherein a first line perpendicular to the cylindrical body and passing through the first extraction aperture and a second line perpendicular to the cylindrical body and passing through the second extraction aperture intersect within the plasma chamber and form an angle of between 30° and 150°.

15. The processing system of claim 14, wherein the at least one antenna element comprises three antenna elements, wherein the three antenna elements are arranged such that a peak plasma density is located at an intersection of the first line and the second line.

16. The processing system of claim 13, further comprising a first external plate having a first defining aperture disposed outside the plasma chamber proximate the first extraction aperture, and a second external plate having a second defining aperture disposed outside the plasma chamber proximate the second extraction aperture, wherein the first external plate and the second external plate are biased at a same voltage as the chamber housing, such that the first defining aperture narrows a path of travel for particles exiting the first extraction aperture and the second defining aperture narrows a path of travel for particles exiting the second extraction aperture.

17. The processing system of claim 13, further comprising a first external plate having a first electrode aperture disposed outside the plasma chamber proximate the first extraction aperture, and a second external plate having a second electrode aperture disposed outside the plasma chamber proximate the second extraction aperture, wherein the first external plate and the second external plate are negatively biased relative to the chamber housing using an electrode power supply so as to attract ions through the first extraction aperture and the second extraction aperture.

18. The processing system of claim 17, further comprising at least a second set of external plates, wherein the second set of external plates are disposed outside the first external plate and second external plate, respectively, and are biased at a different voltage than the first external plate and the second external plate.

19. A processing system, comprising:
a plasma source, comprising:
a chamber housing including a body having a polygonal cross-section and two ends that define a plasma chamber;
a first extraction aperture and a second extraction aperture disposed on two different sides of the body; and
at least one antenna element disposed within the plasma chamber to generate a plasma;
a scan motor; and
a workpiece holder, movable in a scanning direction by the scan motor, wherein a workpiece disposed on the workpiece holder is exposed to particles or ions exiting the first extraction aperture at some locations along the scanning direction, and is exposed to particles or ions exiting the second extraction aperture at other locations along the scanning direction.
